(19) United States
(12) Patent Application Publication
(10) Pub. No.: US 2018/0358463 A1
(43) Pub. Date: Dec. 13, 2018

(54) SEMICONDUCTOR DEVICE AND METHOD OF MANUFACTURING A SEMICONDUCTOR DEVICE

(71) Applicants: FUJI ELECTRIC CO., LTD., Kawasaki-shi (JP); NATIONAL INSTITUTE OF ADVANCED INDUSTRIAL SCIENCE AND TECHNOLOGY, Tokyo (JP)

(72) Inventors: Yusuke KOBAYASHI, Tsukuba-city (JP); Naoyuki OHSE, Matsumoto-city (JP); Shinsuke HARADA, Tsukuba-city (JP); Manabu TAKEI, Tsukuba-city (JP)

(73) Assignees: FUJI ELECTRIC CO., LTD., Kawasaki-shi (JP); NATIONAL INSTITUTE OF ADVANCED INDUSTRIAL SCIENCE AND TECHNOLOGY, Tokyo (JP)

(21) Appl. No.: 15/993,708

(22) Filed: May 31, 2018

(30) Foreign Application Priority Data
Jun. 9, 2017 (JP) 2017-114767

(51) Int. Cl. H01L 29/78; H01L 29/417; H01L 29/16; H01L 29/47

(52) U.S. Cl. CPC H01L 29/7813; H01L 29/7806; H01L 29/47; H01L 29/41766; H01L 29/1608; H01L 29/41741

(57) ABSTRACT

On a front surface of a semiconductor base, a first n⁻-type drift region and a second n-type drift region are provided. A gate trench is provided that penetrates an n⁺-type source region and p-type base region, and reaches the second n-type drift region. Between adjacent gate trenches, a contact trench is provided that penetrates the n⁺-type source region and the p-type base region, and reaches a p-type semiconductor region, through the second n-type drift region. A source electrode embedded in the contact trench is in contact with the p-type semiconductor region at a bottom and corners of the contact trench, and forms a Schottky junction with the second n-type drift region at side walls of the contact trench. A depth of the contact trench is a depth by which a mathematical area of a part thereof forming the Schottky junction is a predetermined mathematical area or greater.

### CROSS REFERENCE TO RELATED APPLICATIONS

This application is based upon and claims the benefit of priority of the prior Japanese Patent Application No. 2017-114767, filed on Jun. 9, 2017, the entire contents of which are incorporated herein by reference.

### BACKGROUND OF THE INVENTION

### 1. Field of the Invention

Embodiments of the invention relate to a semiconductor device and method of manufacturing a semiconductor device.

### 2. Description of the Related Art

Insulated trench-gate type metal oxide semiconductor field effect transistors (MOSFETs) sustaining voltages of 400V, 600V, 1200V, 1700V, 3300V, 6500V or higher are commonly known power semiconductor devices. For example, MOSFETs that use silicon carbide (SiC) (hereinafter, SiC-MOSFETs) are employed in power converting equipment such as converters and inverters. There is demand for these power semiconductor devices to have low loss and high efficiency while at the same time reduce leak current in an OFF state, have a smaller size (reduced chip size), and have greater reliability.

A vertical MOSFET has, as a body diode between a source and a drain, an intrinsic parasitic pn diode formed by a p-type base region and an n-type drift region, thereby enabling a free wheeling diode (FWD) used in inverters to omitted, contributing to reductions in cost and size. On the other hand, when a silicon carbide semiconductor substrate is used as a semiconductor substrate, the parasitic pn diode has high built-in potential compared to a case where a silicon (Si) substrate is used and therefore, ON resistance of the parasitic pn diode increases, leading to increased loss. Further, when the parasitic pn diode is turned ON and energized, characteristics change over time (temporal degradation) due to bipolar operation of the parasitic pn diode and reliability decreases.

This problem will be discussed taking, as an example, a conventional trench-type SiC-MOSFET that includes a contact trench (source trench) between adjacent trenches (for example, refer to Y. Nakano, et al, “690V, 1.00 mΩcm2 4H—SiC Double-Trench MOSFETs”, Materials Science Forum, Switzerland, Trans Tech Publications Inc., 2012, Vol. 717-720, pp. 1069-1072). A gate trench is a trench in which a gate electrode is embedded, via gate insulating film. A contact trench is a trench in which a metal electrode (source electrode) is embedded, the contact trench forming a contact (electrical contact) between the metal electrode and a semiconductor region exposed at an inner wall. First, a structure of the conventional trench-type SiC-MOSFET (hereinafter, a first conventional example) will be described. FIG. 21 is a cross-sectional view of the structure of an active region of the conventional trench-type MOSFET.

As depicted in FIG. 21, the first conventional example includes in the active region, at a front surface of an n-type semiconductor substrate 110, a trench-type MOS gate (insulated gate including a metal oxide film semiconductor material) structure and a contact trench 108. The active region is a region responsible for current driving. In particular, the n-type semiconductor substrate 110 is formed by forming by epitaxial growth on a silicon carbide semiconductor substrate constituting an n⁺-type drain layer 101, an n⁻-type layer that constitutes an n⁻-type drift region 102. At a front surface (surface on an n⁻-type drift region 102 side) side of the n-type semiconductor substrate 110, a MOS gate structure is provided constituted by a p-type base region 103, an n⁺-type source region 104, a gate trench 105, a gate insulating film 106, and a gate electrode 107.

To mitigate electric field applied to the gate insulating film 106 at a bottom of the gate trench 105, a depth of the p-type base region 103 between (mesa portion) adjacent gate trenches 105 is at least partially deeper than a depth of the gate trench 105. To make the depth of the p-type base region 103 deeper than the depth of the gate trench 105, at the mesa portion, the contact trench 108 is provided at a depth deeper than the depth of the gate trench 105. The p-type base region 103 is provided along the inner walls of the contact trench 108 entirely so as to cover a source electrode 111 described hereinafter, and protrude more deeply toward a drain than does the gate trench 105. Further, the p-type base region 103 is exposed at the inner walls of the contact trench 108.

The n⁺-type source region 104 is selectively provided in the p-type base region 103, between the contact trench 108 and each gate trench 105 adjacent to the contact trench 108. The n⁺-type source region 104 and the p-type base region 103 exposed at the inner walls of the contact trench 108 are exposed at a contact hole 109a penetrating an interlayer insulating film 109 in a depth direction. The source electrode 111 is provided as a front electrode, so as to be embedded in the contact hole 109a and the contact trench 108, and so as to be in contact with the p-type base region 103 and the n⁺-type source region 104. At a rear surface (surface on an n⁺-type drain layer 101 side) of the n-type semiconductor substrate 110, a drain electrode (not depicted) is provided as a rear electrode.

When positive voltage is applied to the source electrode 111 and negative voltage is applied to the drain electrode (OFF state of MOSFET), a pn junction between the p-type base region 103 and the n⁻-type drift region 102 is forward biased. In the first conventional example, when the MOSFET is OFF, a parasitic pn diode formed by the p-type base region 103 and the n⁻-type drift region 102 is turned ON and energized, whereby temporal degradation occurs due to the bipolar operation of the parasitic pn diode. Further, when the parasitic pn diode is used as a free wheeling diode, use of a silicon carbide semiconductor substrate increases the ON resistance. This problem is resolved by building in a parasitic Schottky diode between the source and the drain, as a body diode (for example, refer to Japanese Laid-Open Patent Publication No. 2011-134910, Japanese Laid-Open Patent Publication No. 2008-117826).

A silicon carbide semiconductor material has a higher critical electric field strength against avalanche breakdown as compared to a silicon semiconductor material and therefore, even for breakdown voltages of 600V or higher, a parasitic Schottky diode may be used as a body diode. In particular, a parasitic Schottky diode is provided in parallel to a parasitic pn diode between the source and the drain, and design is such that when the MOSFET turns OFF, the parasitic Schottky diode turns ON before the parasitic pn diode turns ON. As a result, temporal degradation due to the bipolar operation of the parasitic pn diode may be prevented. Further, since the pn junction has no built-in potential, the parasitic Schottky diode may be expected to have a lower ON resistance as compared to a case where the parasitic pn diode alone is formed as a body diode.

### SUMMARY OF THE INVENTION

According to an embodiment of the present invention, a semiconductor device includes a first silicon carbide semiconductor layer of a first conductivity type; a second silicon carbide semiconductor layer of the first conductivity type provided on a surface of the first silicon carbide semiconductor layer, an impurity concentration of the second silicon carbide semiconductor layer being lower than an impurity concentration of the first silicon carbide semiconductor layer; a first semiconductor region of a second conductivity type selectively provided in the second silicon carbide semiconductor layer, at a position deeper than a surface of the second silicon carbide semiconductor layer; a third silicon carbide semiconductor layer of the second conductivity type provided on the surface of the second silicon carbide semiconductor layer; a second semiconductor region of the first conductivity type selectively provided in the third silicon carbide semiconductor layer; a first trench that penetrates the second semiconductor region and the third silicon carbide semiconductor layer, and reaches the second silicon carbide semiconductor layer; a second trench provided separated from the first trench, the second trench penetrating the second semiconductor region and the third silicon carbide semiconductor layer, and reaching the first semiconductor region, through the second silicon carbide semiconductor layer; a gate electrode provided in the first trench, on a gate insulating film; and a metal electrode in contact with the second semiconductor region and the third silicon carbide semiconductor layer, the metal electrode being embedded in the second trench so as to be in contact with the first semiconductor region at a bottom and corners of the second trench, the metal electrode forming a Schottky junction with the second silicon carbide semiconductor layer at a side wall of the second trench. A depth of the second trench is a depth by which a mathematical area of the metal electrode forming the Schottky junction is at least a predetermined mathematical area.

In the embodiment, the semiconductor device further includes a third semiconductor region of the second conductivity type selectively provided in the second silicon carbide semiconductor layer, the third semiconductor region opposing the gate electrode at the bottom and the corners of the first trench, across the gate insulating film.

In the embodiment, a depth of an interface of the third semiconductor region and the second silicon carbide semiconductor layer nearest the first silicon carbide semiconductor layer and a depth of an interface of the first semiconductor region and the second silicon carbide semiconductor layer nearest the first silicon carbide semiconductor layer are equal.

In the embodiment, the semiconductor device further includes a fourth semiconductor region of the second conductivity type provide in the second silicon carbide semiconductor layer, at a position deeper than the third semiconductor region. A depth of an interface of the fourth semiconductor region and the second silicon carbide semiconductor layer nearest the first silicon carbide semiconductor layer and a depth of an interface of the first semiconductor region and the second silicon carbide semiconductor layer nearest the first silicon carbide semiconductor layer are equal.

In the embodiment, the semiconductor device further includes a first silicon carbide semiconductor region of the second conductivity type provided on the surface of the second silicon carbide semiconductor layer, an impurity concentration of the first silicon carbide semiconductor region being higher than the impurity concentration of the second silicon carbide semiconductor layer. The third silicon carbide semiconductor layer is provided on a first side of the first silicon carbide semiconductor region opposite a second side of the first silicon carbide semiconductor region, the second side facing the second silicon carbide semiconductor layer. The first semiconductor region is provided in the second silicon carbide semiconductor layer, closer to the first silicon carbide semiconductor layer than is an interface of the second silicon carbide semiconductor layer and the first silicon carbide semiconductor region. The third semiconductor region is provided in the first silicon carbide semiconductor region.

In the embodiment, a width of the first semiconductor region is wider than a width of second trench.

In the embodiment, a depth of the second trench is at least equal to a depth of the first trench.

In the embodiment, a depth of the second trench is in a range from 1.8 μm to 3.0 μm.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of an active region of a semiconductor device according to a first embodiment;

FIG. 2 is a diagram of operation of the semiconductor device according to the first embodiment during an OFF state;

FIG. 3 is a cross-sectional view of the semiconductor device according to the first embodiment during manufacture;

FIG. 4 is a cross-sectional view of the semiconductor device according to the first embodiment during manufacture;

FIG. 5 is a cross-sectional view of the semiconductor device according to the first embodiment during manufacture;

FIG. 6 is a cross-sectional view of the semiconductor device according to the first embodiment during manufacture;

FIG. 7 is a cross-sectional view of the semiconductor device according to the first embodiment during manufacture;

FIG. 8 is a cross-sectional view of the semiconductor device according to the first embodiment during manufacture;

FIG. 9 is a cross-sectional view of a structure of the active region of the semiconductor device according to a second embodiment;

FIG. 10 is a cross-sectional view of the semiconductor device according to the second embodiment during manufacture;

FIG. 11 is a cross-sectional view of the semiconductor device according to the second embodiment during manufacture;

FIG. 12 is a cross-sectional view of the semiconductor device according to the second embodiment during manufacture;

FIG. 13 is a cross-sectional view of a structure of the active region of the semiconductor device according to a third embodiment;

FIG. 14 is a cross-sectional view of the semiconductor device according to the third embodiment during manufacture;

FIG. 15 is a cross-sectional view of the semiconductor device according to the third embodiment during manufacture;

FIG. 16 is a cross-sectional view of a structure of the active region of the semiconductor device according to a fourth embodiment;

FIG. 17 is a cross-sectional view of the semiconductor device according to the fourth embodiment during manufacture;

FIG. 18 is a cross-sectional view of the semiconductor device according to the fourth embodiment during manufacture;

FIG. 19 is a cross-sectional view of a structure of the active region of the semiconductor device according to a fifth embodiment;

FIG. 20 is a cross-sectional view of the semiconductor device according to the fifth embodiment during manufacture;

FIG. 21 is a cross-sectional view of a structure of an active region of a conventional trench-type MOSFET; and

FIG. 22 is a cross-sectional view of another example of a structure of the active region of a conventional trench-type MOSFET.

### DETAILED DESCRIPTION OF THE INVENTION

First problems associated with the related arts will be discussed. In Japanese Laid-Open Patent Publication No. 2011-134910, when the MOSFET is in the OFF state, high electric field is applied to a Schottky junction formed at the bottom of the contact trench, whereby a problem arises in that large leak current flows via the Schottky junction.

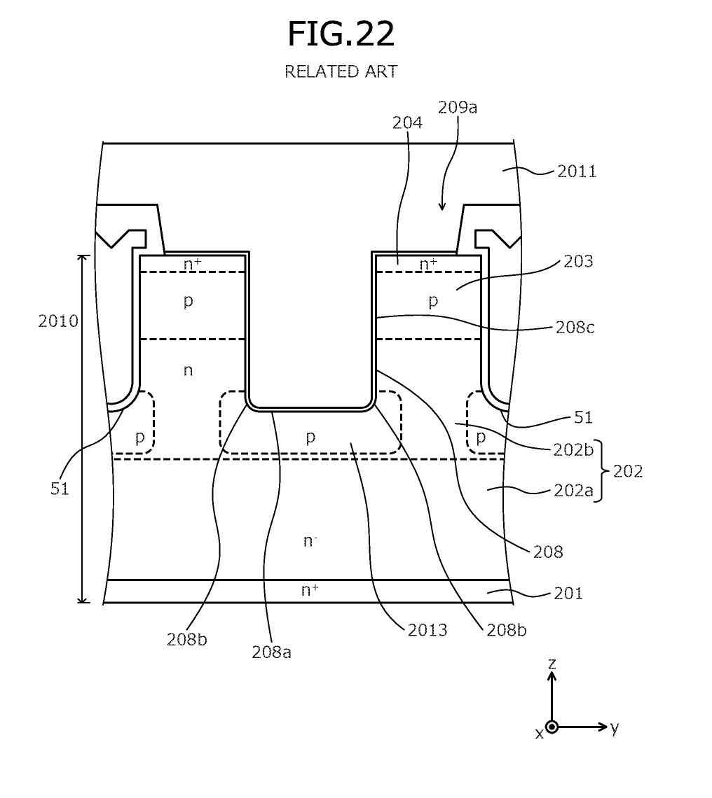

Therefore, a semiconductor device has been proposed that prevents temporal degradation due to the bipolar operation of the parasitic pn diode and reduces leak current (hereinafter, second conventional example). For example, FIG. 22 is a cross-sectional view of another example of a structure of the active region of a conventional trench-type MOSFET.

In the second conventional example, as depicted in FIG. 22, at a front surface of a semiconductor base 2010 that is formed by sequentially forming a n-type drift region 202 and a p-type base region 203 by epitaxial growth on an n⁺-type drain layer 201, gate trenches 51 that penetrate an n⁺-type source region 204 and the p-type base region 203, and reach a second n-type drift region 202b are provided. In the second n-type drift region 202b, a p-type semiconductor region 2013 is selectively provided. Between adjacent gate trenches 51, a contact trench 208 that penetrates the n⁺-type source region 204 and the p-type base region 203, and reaches a p-type semiconductor region 2013 via the second n-type drift region 202b is provided. A source electrode 2011 embedded in the contact trench 208 is in contact with the p-type semiconductor region 2013 at a bottom 208a and corners 208b of the contact trench 208, and forms a Schottky junction with the second n-type drift region 202b, at a side wall 208c of the contact trench 208.

In the second conventional example, since the Schottky junction of the n-type drift region and the metal electrode is formed only at the side wall of the contract trench, when the parasitic Schottky diode formed by the n-type drift region and the metal electrode is ON, the parasitic pn diode formed by the p-type base region and the n-type drift region does not turn ON. Therefore, temporal degradation due to the bipolar operation of the parasitic pn diode does not occur.

Further, at the entire surface of the corners and the bottom of the contact trench, the metal electrode is covered by a p-type drift region, whereby when the MOSFET is OFF, the electric field applied to the Schottky junction of the n-type drift region and the metal electrode may be mitigated. As a result, leak current of the parasitic Schottky diode maybe reduced.

Further, the p-type semiconductor region spans the entire surface of the corners and the bottom of the gate trench and covers the gate electrode via the gate insulating film, whereby the electric field applied to the gate insulating film at the bottom of the gate trench may be mitigated.

Nonetheless, with the trench-type silicon carbide semiconductor device depicted in FIG. 22, a mathematical area of the Schottky junction per unit area of the SiC-MOSFET does not change and therefore, current flow that flows in the parasitic Schottky diode cannot be set to be a predetermined magnitude. Thus, in some cases bipolar operation of the parasitic pn diode at the time of flyback cannot be suppressed, defects in the parasitic pn diode occur, and forward loss occurs. Further, with Japanese Laid-Open Patent Publication No. 2008-117826, similarly, since the mathematical area of the Schottky junction per unit area of the MOSFET does not change, the current that flows in the parasitic Schottky diode cannot be set to be a predetermined magnitude and thus, in some cases, bipolar operation of the parasitic pn diode at the time of flyback cannot be suppressed, defects in the parasitic pn diode occur, and forward loss occurs.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described.

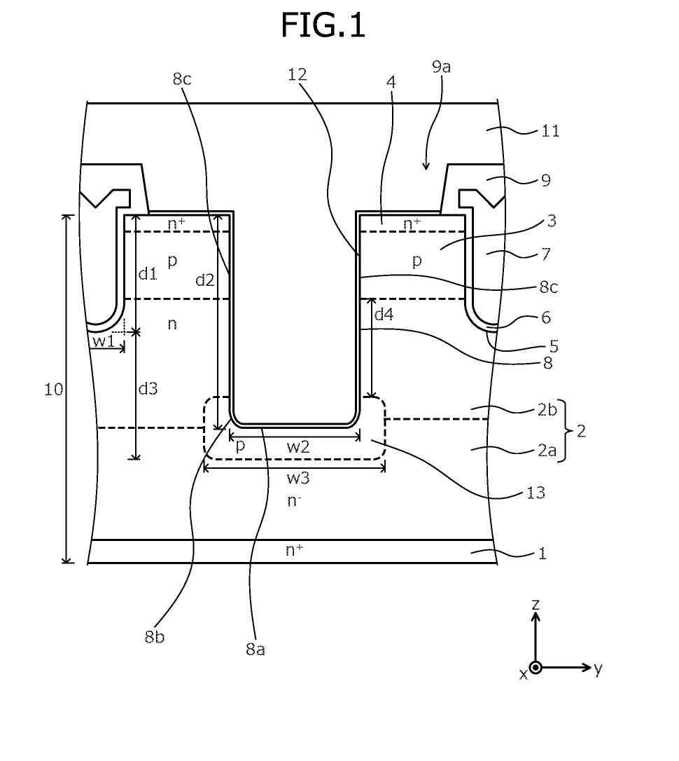

A structure of the semiconductor device according to the first embodiment will be described. FIG. 1 is a cross-sectional view of the structure of an active region of the semiconductor device according to a first embodiment. The semiconductor device according to the first embodiment depicted in FIG. 1 is a trench-type SiC-MOSFET that includes in an active region, at a front surface side of a semiconductor base (semiconductor chip) 10, a gate trench (first trench) 5 and a contact trench (second trench) 8. The active region is a region responsible for current driving (region through which current flows in an ON state). The gate trench 5 is a trench in which a gate electrode 7 is embedded, via a gate insulating film 6. The contact trench 8 is a trench in which a front electrode (metal electrode: a source electrode 11 and a metal film 12) described hereinafter is embedded, and that forms a contact (electrical contact) with the front electrode, at inner walls (8a, 8b, 8c).

In particular, as depicted in FIG. 1, the semiconductor base 10 is, for example, a silicon carbide epitaxial substrate formed by sequentially forming by epitaxial growth on an n⁺-type silicon carbide (SiC) substrate (first silicon carbide semiconductor layer) constituting an n⁺-type drain layer 1, an n-type epitaxial layer (second silicon carbide semiconductor layer) constituting an n-type drift region 2 and a p-type epitaxial layer (third silicon carbide semiconductor layer) constituting a p-type base region 3. The n-type drift region 2 is constituted by, an n⁻-type region (hereinafter, first n⁻-type drift region) 2a and an n-type region (hereinafter, second n-type drift region) 2b sequentially stacked on the n⁺-type drain layer 1 and having mutually differing impurity concentrations. At a front surface (surface on an epitaxial layer side) side of the semiconductor base 10, a trench-type MOS gate structure is provided constituted by the p-type base region 3, an n⁺-type source region (second semiconductor region) 4, the gate trench 5, the gate insulating film 6, and the gate electrode 7.

The p-type base region 3 is formed by epitaxial growth on a first surface (surface of a second n-type drift region 2b) of the n-type drift region 2, opposite a second surface of the n-type drift region 2, the second surface being toward the n⁺-type drain layer 1. The n⁺-type source region 4 is selectively formed in the p-type base region 3, for example, by ion implantation. The n⁺-type source region 4 opposes the gate electrode 7, across the gate insulating film 6.

The gate trench 5 is arranged in a striped planar layout extending along a first direction x. The gate trench 5 penetrates the n⁺-type source region 4 and the p-type base region 3 from a base front surface and reaches the second n-type drift region 2b. In the gate trench 5, the gate insulating film 6 is provided along inner walls of the gate trench 5, and the gate electrode 7 is provided on the gate insulating film 6. In other words, the gate electrode 7 opposes the n⁺-type source region 4 across the gate insulating film 6 provided at side walls of the gate trench 5. In FIG. 1, although only between (mesa portion) adjacent gate trenches 5 is depicted, the gate trench 5 is arranged for each unit cell (functional unit of an element) arranged in the active region (similarly for other drawings depicting the gate trench 5).

The contact trench 8 is arranged between adjacent gate trenches 5, in parallel to the gate trenches 5 and separated from the gate trenches 5, in a striped planar layout that extends along a first direction x. For example, when the contact trench 8 is arranged at all of the mesa portions, the gate trench 5 and the contact trench 8 are arranged to repeatedly alternate along a direction (hereinafter, a second direction) y orthogonal to the first direction x. The contact trench 8 penetrates the n⁺-type source region 4 and the p-type base region 3 from base front surface, and reaches a p-type semiconductor region 13 described hereinafter through the second n-type drift region 2b. A depth d2 of the contact trench 8 is equal to a depth d1 of the gate trench 5 or more (d2≥d1). A width w2 of the contact trench 8 may be wider than a width w1 of the gate trench 5 (w2>w1).

In the n-type drift region 2, at an interface of the first n⁻-type drift region 2a and the second n-type drift region 2b, the p-type semiconductor region (first semiconductor region) 13 is selectively provided. The contact trench 8 reaches the p-type semiconductor region 13 and the p-type semiconductor region 13 is exposed at the entire surface of corners 8b and a bottom 8a of the contact trench 8. The corners 8b of the contact trench 8 are locations where the bottom 8a and side walls 8c of the contact trench 8 join, and are corners curved at a predetermined curvature. A width w3 of the p-type semiconductor region 13 is wider than a width w2 of the contact trench 8 (w3>w2). In other words, the p-type semiconductor region 13 is exposed at the bottom 8a and the corners 8b of the contact trench 8, and the n⁺-type source region 4, the p-type base region 3, and the second n-type drift region 2b are exposed at the side walls 8c of the contact trench 8.

From a bottom of the gate trench 5 to a bottom surface (surface toward the drain) of the p-type semiconductor region 13 may be separated by a distance d3 that enables mitigation of electric field to an extent that prevents dielectric breakdown of the gate insulating film 6 at the bottom of the gate trench 5.

An interlayer insulating film 9 is provided so as to cover the gate electrode 7. In a contact hole 9a that penetrates the interlayer insulating film 9 in a depth direction z, the n⁺-type source region 4 exposed at the base front surface is exposed, and the described semiconductor regions exposed at the inner walls of the contact trench 8 are exposed. Along the base front surface exposed in the contact hole 9a and the inner walls of the contact trench 8, the metal film 12 containing, for example, nickel (Ni) is provided. The metal film 12 functions as the source electrode 11 described hereinafter and a front electrode. The metal film 12 spans the side walls 8c of the contact trench 8, from the base front surface and is in contact with the n⁺-type source region 4. As a result, a mathematical contact area of the front electrode and the n⁺-type source region 4 formed at the base front surface side increases, enabling contact resistance to be reduced. Further, size reductions become possible without increases in the contact resistance.

The metal film 12 spans the entire surface of the corners 8b, from the bottom 8a of the contact trench 8, and is in contact with the p-type semiconductor region 13. The metal film 12 is in contact with the second n-type drift region 2b at the side walls 8c of the contact trench 8, and forms a Schottky junction with the second n-type drift region 2b. In other words, only a part of the side walls 8c of the contact trench 8 from the pn junctions with the p-type base region 3 to an upper end (end toward a source) of the p-type semiconductor region 13 forms the Schottky junction. A distance d4 (along the depth direction z) of the part of the side walls 8c of the contact trench 8 forming the Schottky junction may be a height whereby a mathematical area of the part forming the Schottky junction is a predetermined mathematical area or greater.

As a result, a mathematical contact area of the second n-type drift region 2b and the front electrode increases, the current that flows through the parasitic Schottky diode may be increased, and the current that flows through the parasitic pn diode may be relatively decreased. For example, when the current flowing through the parasitic pn diode relative to the current flowing through the parasitic Schottky diode (hereinafter, B/U) exceeds 1.0, characteristics change over time due to bipolar operation and therefore, B/U may be 1.0 or less. Thus, the mathematical area of the part forming the Schottky junction may be at least a predetermined mathematical area by which B/U is 1.0 or less. The mathematical area is determined by a ratio (P/S) of a width of a P layer of a trench bottom per unit cell and a width of the part forming the Schottky junction, and P/S may be 0.4 or greater.

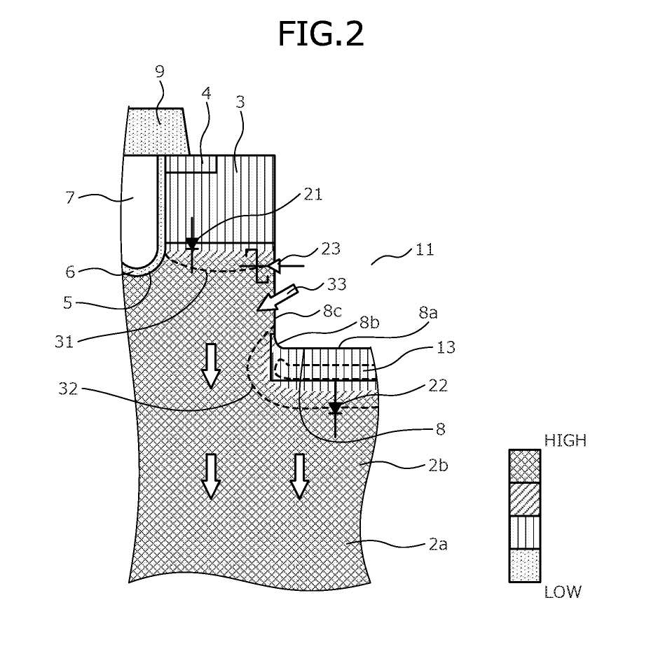

The source electrode 11 is provided in the contact hole 9a and the contact trench 8, via the metal film 12, and is electrically connected with the n⁺-type source region 4, the p-type base region 3, the second n-type drift region 2b, and the p-type semiconductor region 13. As a result, when the MOSFET is OFF, as described hereinafter, at the corners 8b and the bottom 8a of the contact trench 8, a parasitic pn diode 22 of the p-type semiconductor region 13 and the second n-type drift region 2b is formed (refer to FIG. 2). Further, at the side walls 8c of the contact trench 8, a parasitic Schottky diode 23 of the second n-type drift region 2b and the front electrode (the source electrode 11 and the metal film 12) is formed. In other words, between the source and the drain, the parasitic Schottky diode 23 is formed in parallel with a parasitic pn diode 21 (refer to FIG. 2). At a rear surface (surface on the n⁺-type drain layer 1 side) of the semiconductor base 10, a drain electrode (not depicted) is provided as a rear electrode. The n⁺-type drain layer 1 has a function of reducing contact resistance with the drain electrode.

Operation (current flow) of the semiconductor device according to the first embodiment during the OFF state will be described. FIG. 2 is a diagram of operation of the semiconductor device according to the first embodiment during the OFF state. In FIG. 2, flow of a current 33 during the OFF state in the MOSFET depicted in FIG. 1 is indicated by white arrows. In FIG. 2, the metal film 12 depicted in FIG. 1 is not depicted. When positive voltage is applied to the front electrode and negative voltage is applied to the drain electrode (OFF state of the MOSFET), near the corners 8b and the bottom 8a of the contact trench 8, a depletion layer 32 spreads from the pn junction between the p-type semiconductor region 13 and the second n-type drift region 2b. As described, the Schottky junction of the second n-type drift region 2b and the front electrode is formed at the side walls 8c of the contact trench 8 and therefore, due to the depletion layer 32 spreading from the pn junction between the p-type semiconductor region 13 and the second n-type drift region 2b, electric field is less likely to be applied to the parasitic Schottky diode 23 during the OFF state.

Reference numeral 31 is a depletion layer that spreads during the OFF state of the MOSFET, from a pn junction of the p-type base region 3 and the second n-type drift region 2b. Further, during the ON state, without passing through the parasitic pn diode 21 formed by the p-type base region 3 and the second n-type drift region 2b, the current 33 flows from the source side toward the drain side, passing through the parasitic Schottky diode 23 formed at the side walls 8c of the contact trench 8. In other words, during the ON state, among the body diodes formed in silicon carbide semiconductor substrate, only the parasitic Schottky diode 23 operates; and the parasitic pn diode 21 formed by the p-type base region 3 and the second n-type drift region 2b, and the parasitic pn diode 22 formed by the p-type semiconductor region 13 and the second n-type drift region 2b do not operated. Therefore, temporal degradation due to the parasitic pn diodes 21, 22 turning ON and performing bipolar operation does not occur.

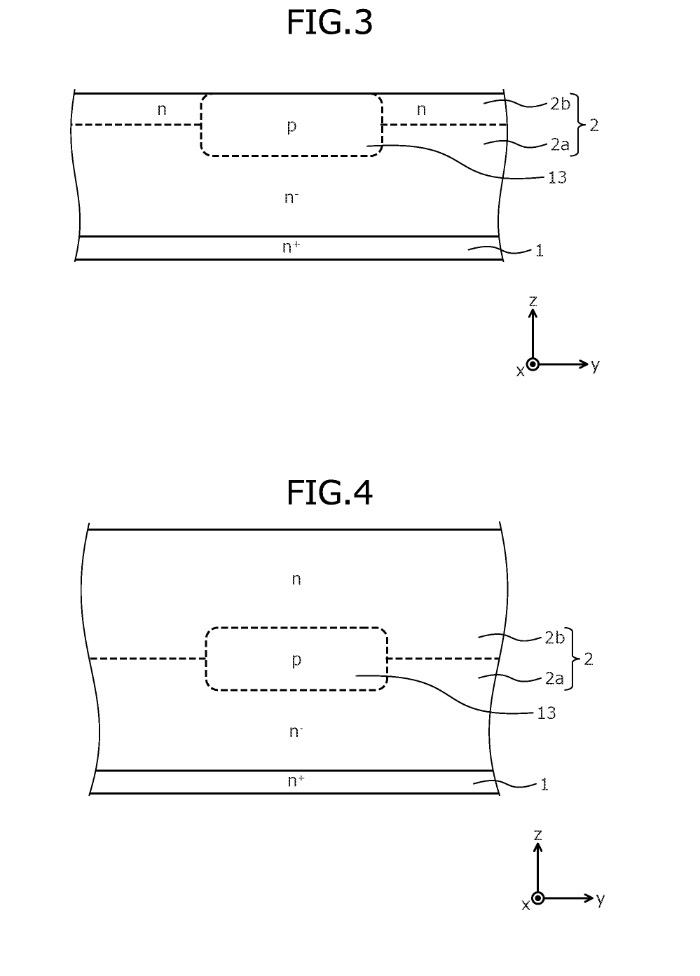

A method of manufacturing the semiconductor device according to the first embodiment will be described taking, as an example, a case where a 1200V trench-type SiC-MOSFET is fabricated (manufactured). FIGS. 3, 4, 5, 6, 7, and 8 are cross-sectional views of the semiconductor device according to the first embodiment during manufacture. First, on a front surface of the silicon carbide semiconductor substrate (semiconductor wafer) constituting the n⁺-type drain layer 1, an n⁻-type epitaxial layer constituting the first n⁻-type drift region 2a and having a thickness of, for example, 10 μm is deposited (formed). An impurity concentration of the n⁺-type drain layer 1 may be in a range of, for example, about 1×10¹⁸/cm³ to 1×10²⁰/cm³. An impurity concentration of the first n⁻-type drift region 2a may be in a range of, for example, about 2×10¹⁵/cm³ to 2×10¹⁶/cm³.

Next, by photolithography and ion implantation of a p-type impurity such as aluminum (Al), the p-type semiconductor region 13 is selectively formed in a surface layer of the first n⁻-type drift region 2a, at a depth in a range of about 0.3 μm to 1.5 μm. An impurity concentration of the p-type semiconductor region 13 may be in a range of, for example, about 1×10¹⁶/cm³ to 1×10¹⁸/cm³. Next, by photolithography and ion implantation of an n-type impurity such as phosphorus (P) or nitrogen (N), the second n-type drift region 2b is formed in the surface layer of the first n⁻-type drift region 2a in the active region, at a depth in a range of, for example, about 0.3 μm to 1.5 μm. An impurity concentration of the second n-type drift region 2b may be in a range of, for example, about 1×10¹⁶/cm³ to 1×10¹⁸/cm³. A depth of the second n-type drift region 2b may be equal to a depth of the p-type semiconductor region 13 or less.

The width w3 of the p-type semiconductor region 13, for example, may be of a width extending beyond both side walls of the contact trench 8 (formed subsequently) by about 0.05 μm or more; and in particular, may be in a range of about 0.05 μm to 5.0 μm. A reason for this is that when the width w3 of the p-type semiconductor region 13 is less than this range, the leak current during the OFF state of the MOSFET increases, and when the width w3 exceeds than this range, achieving higher performance by cell pitch reduction becomes difficult. Further, as described, from the perspective of electric field mitigation at the gate insulating film 6, the distance d3 from the bottom of the gate trench 5 to the bottom surface (surface toward the drain) of the p-type semiconductor region 13 may be, for example, about 1.0 μm or greater and therefore, the depth of the second n-type drift region 2b is determined. The state up to here is depicted in FIG. 3.

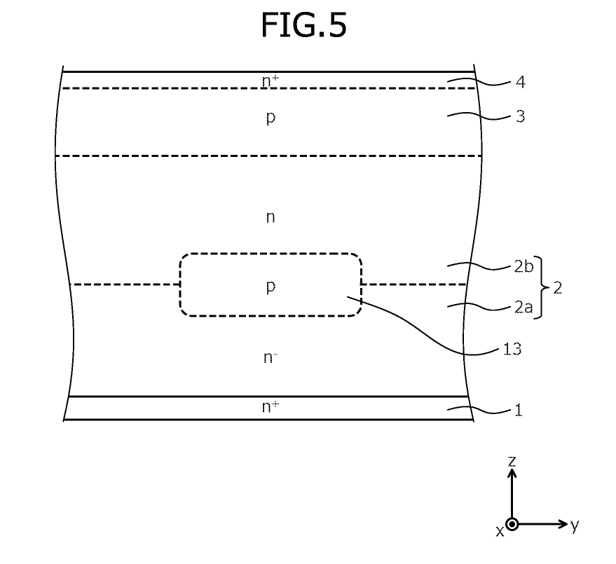

Next, an n⁻-type epitaxial layer having an impurity concentration in a range of, for example, about 1×10¹⁶/cm³ to 1×10¹⁸/cm³ and a thickness in a range of, for example, about 0.3 μm to 3.0 μm is formed by epitaxial growth so as to cover the p-type semiconductor region 13. Next, by photolithography and ion implantation of an n-type impurity such as phosphorus (P) or nitrogen (N), the second n-type drift region 2b is formed from the n⁻-type epitaxial layer, and a thickness of the second n-type drift region 2b is increased. The state up to here is depicted in FIG. 4.

Next, a p-type epitaxial layer constituting the p-type base region 3 and having a thickness in a range of, for example, about 0.3 μm to 2.0 μm is formed on a surface of the second n-type drift region 2b, by epitaxial growth. By the processes up to here, the semiconductor base (silicon carbide epitaxial wafer) 10 in which the n-type epitaxial layer constituting the n-type drift region 2 and the p-type epitaxial layer constituting the p-type base region 3 are sequentially grown on the silicon carbide semiconductor substrate constituting the n⁺-type drain layer 1 is fabricated. An impurity concentration of the p-type base region 3 may be in a range of, for example, about 1×10¹⁵/cm³ to 1×10¹⁹/cm³.

Next, by photolithography and ion implantation of an n-type impurity such as phosphorus or nitrogen, the n⁺-type source region 4 is selectively formed in a surface layer of the p-type base region 3. An impurity concentration of the n⁺-type source region 4 may be in a range of, for example, about 1×10¹⁸/cm³ to 1×10²⁰/cm³. A depth of the n⁺-type source region 4 may be in a range of, for example, about 0.1 μm to 0.5 μm. Next, on the base front surface (surface on the n⁺-type source region 4 side), a carbon cap is deposited (formed), activation annealing is performed, and the carbon cap is removed. The state up to here is depicted in FIG. 5.

Next, on the base front surface (surface on the n⁺-type source region 4 side), an oxide film having a thickness in a range of, for example, about 1.5 μm to 2.5 μm is deposited (formed). Next, by photolithography and etching, the oxide film is patterned, and a part of the oxide film corresponding to the contact trench 8 is removed. Next, a resist mask (not depicted) used in patterning the oxide film is removed and thereafter, etching is performed using, as a mask, the oxide film that remains, and the contact trench 8 is formed at the depth d2 at which the bottom 8a and the corners 8b reach the p-type semiconductor region 13.

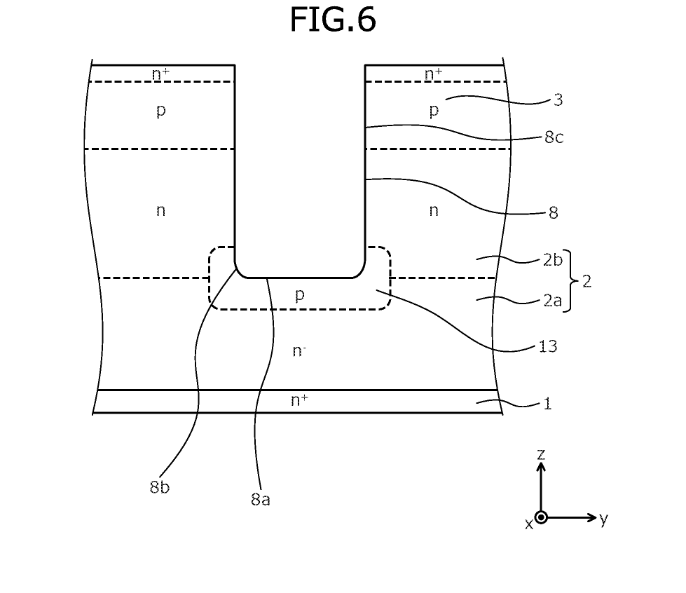

At this time, the second n-type drift region 2b is exposed at the side walls 8c of the contact trench 8 so that the distance d4 (in the depth direction z) of the Schottky junction formed afterwards at the side walls 8c of the contact trench 8 satisfies the above range. In particular, the depth d2 of the contact trench 8 may be the depth d1 of the gate trench 5 described hereinafter or greater and may be in a range of, for example, about 1.8 μm to 3.0 μm. Further, the width w2 of the contact trench 8 may be in a range of, for example, about 0.1 μm to 3.0 μm. After trench etching, isotropic etching for removing damage of the trench and hydrogen annealing for rounding the bottom of the trench and opening of the trench may be performed. Either the isotropic etching or the hydrogen annealing alone may be performed. Alternatively, after the isotropic etching is performed, the hydrogen annealing may be performed. The state up to here is depicted in FIG. 6.

Next, the oxide film that remains, for example, is removed by hydrofluoric acid (HF) and thereafter, on the base front surface, an oxide film having a thickness in a range of, for example, about 1.5 μm to 2.5 μm is newly deposited (formed). Next, by photolithography and etching, the oxide film is patterned and a part of the oxide film corresponding to the gate trench 5 is removed. Next, a resist mask (not depicted) used in patterning the oxide film is removed and thereafter, etching is performed using, as a mask, the oxide film that remains, and the gate trench 5 is formed. The depth d1 of the gate trench 5 may be in a range of, for example, about 1.0 μm to 2.0 μm. The width w1 of the gate trench 5 may be in a range of, for example, about 0.5 μm to 2.0 μm. A sequence in which the gate trench 5 and the contact trench 8 are formed may be interchanged.

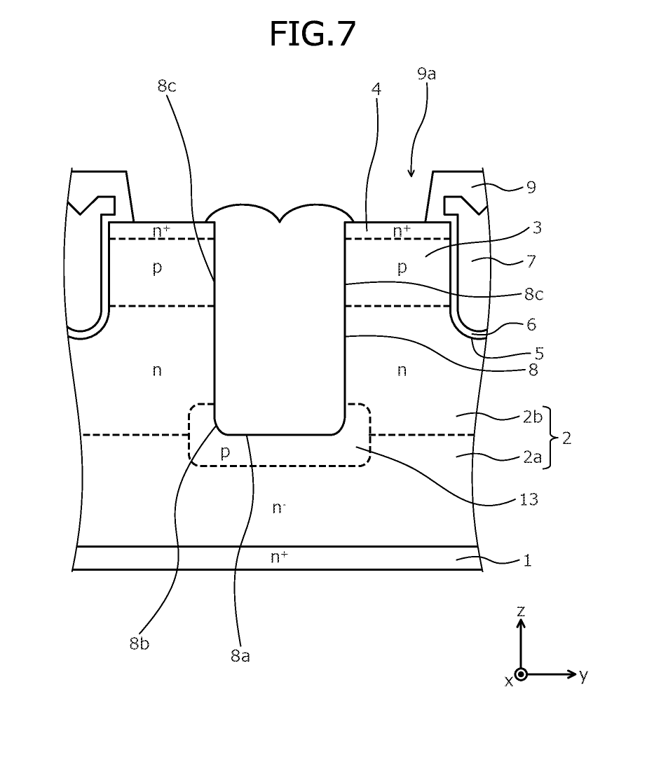

Next, the oxide film that remains is removed and thereafter, along the inner walls of the gate trench 5, an oxide film (SiO₂ film) 43 constituting the gate insulating film 6 and having a thickness in a range of, for example, about 10 nm to 500 nm is deposited (formed), and heat treatment is performed in a nitrogen (N₂) atmosphere at a temperature in a range of about 800 degrees C. to 1200 degrees C. Next, for example, a poly-silicon (poly-Si) layer having a thickness in a range of 0.3 μm to 1.5 μm is deposited (formed) on the base front surface so as to be embedded in the gate trench 5, on the oxide film. Next, by photolithography and etching, the poly-silicon layer is patterned, forming the gate electrode 7. Next, an oxide film having a thickness in a range of, for example, about 0.5 μm to 1.5 μm is deposited (formed) on the base front surface, as the interlayer insulating film 9. Next, by photolithography and etching, the interlayer insulating film 9 is patterned, forming the contact hole 9a. The state up to here is depicted in FIG. 7.

Next, at the rear surface of the semiconductor base 10, by sputtering deposition at a contact part of the drain electrode, a metal film such as a nickel (Ni) film, a titanium (Ti) film, a tungsten (W) film, etc. is formed. The metal film may be constituted by a combination of multiple Ni, Ti, W films. Thereafter, annealing such as rapid thermal annealing (RTA) is performed to convert the metal film into a silicide and form an ohmic contact. Thereafter, for example, a thick film constituted by a Ti film, an Ni film, and a gold (Au) film sequentially stacked in order stated is formed by electron beam (EB) deposition, etc., whereby the drain electrode is formed.

Next, by photolithography and etching, the oxide film in the contact trench 8 is removed, and the metal film 12, for example, an Ni film is deposited (formed) along the inner walls of the contact trench 8 and the base front surface. Next, by sintering (heat treatment) at a temperature in a range of, for example, 400 degrees C. to 900 degrees C., silicon carbide semiconductor parts (the n⁺-type source region 4 and the p-type base region 3) and the Ni film are caused to react and form a nickel silicide film. As a result, a Schottky junction with the second n-type drift region 2b, and an ohmic contact of the p-type base region 3 and the n⁺-type source region 4 are formed.

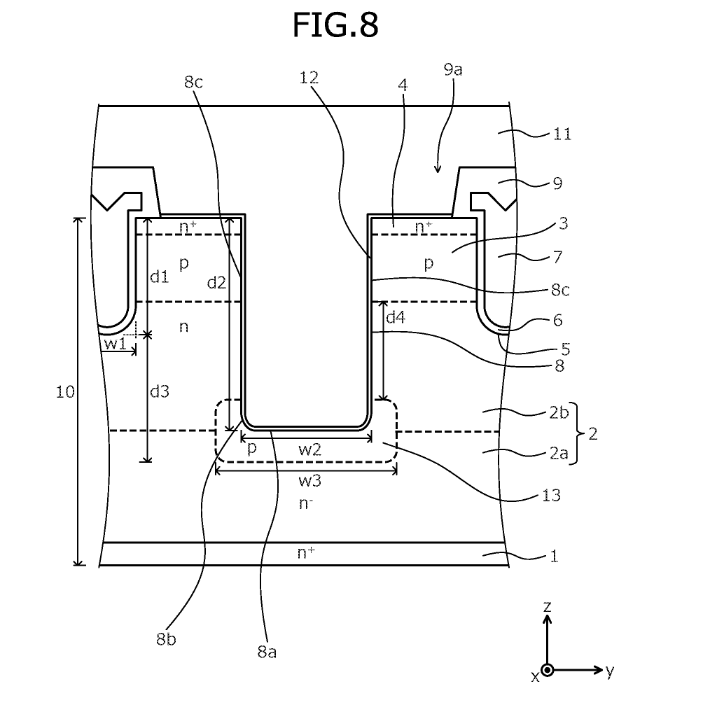

Next, for example, by a sputtering method, for example, an aluminum film is provided so as to cover the source electrode 11 and the interlayer insulating film 9, and have a thickness of, for example, about 5 μm. Thereafter, the aluminum film is selectively removed so that the aluminum film that remains covers the active region, forming a source electrode pad. Next, an oxide film is patterned, exposing semiconductor regions. As a result, at an opening (i.e., the contact hole 9a) of a resist film used in patterning of the interlayer insulating film 9, the n⁺-type source region 4, the p-type base region 3, the second n-type drift region 2b and the p-type semiconductor region 13 are exposed at the base front surface and the inner walls of the contact trench 8. The state up to here is depicted in FIG. 8. Thereafter, the wafer is diced into individual chips, whereby the trench-type SiC-MOSFET depicted in FIG. 1 is completed.

As described, according to the first embodiment, the mathematical area of the part of the side walls of the contact trench where the Schottky junction is formed may be set to be a predetermined mathematical area or greater. As a result, the mathematical contact area of the second n-type drift region and the front electrode increases, the current that flows through the parasitic Schottky diode may be increased, and the current that flows through the parasitic pn diode may be relatively decreased. For example, the current flowing through the parasitic pn diode relative to the current flowing through the parasitic Schottky diode may be set to be 1.0 or less, the current flowing through the parasitic pn diode at the time of flyback may be reduced, and defects occurring at the parasitic pn diode may be reduced. Therefore, the occurrence of defects at the parasitic pn diode is suppressed, enabling forward loss to be reduced.

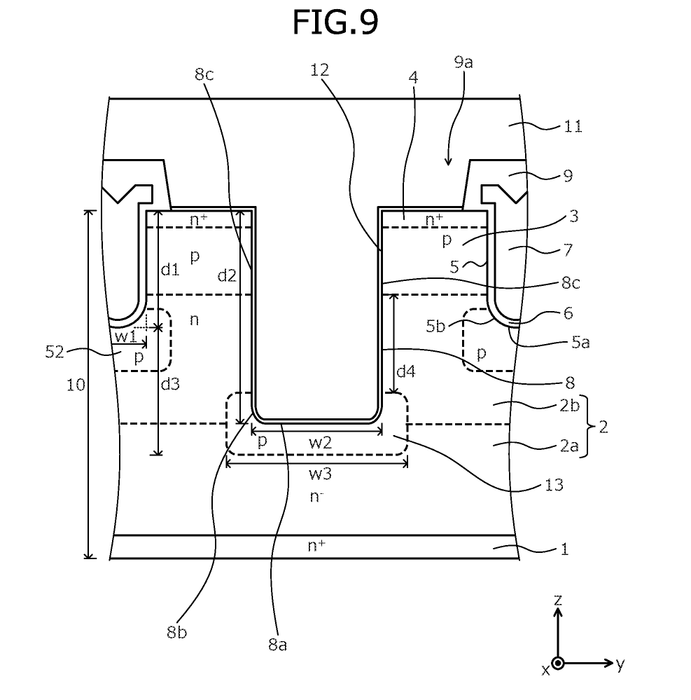

A structure of the semiconductor device according to a second embodiment will be described. FIG. 9 is a cross-sectional view of the structure of the active region of the semiconductor device according to the second embodiment. The semiconductor device according to the second embodiment differs from the semiconductor device according to the first embodiment in that a p-type semiconductor region (hereinafter, second p-type semiconductor region (third semiconductor region) 52 is provided spanning a bottom 5a and corners 5b of the gate trench 5 and covering the gate electrode 7, via the gate insulating film 6.

The second p-type semiconductor region 52 is provided in the second n-type drift region 2b, separated from the p-type semiconductor region 13 at the bottom 8a of the contact trench 8. A width w4 of the second p-type semiconductor region 52 is wider than the width w1 of the gate trench 5 (w4>w1). Provision of the second p-type semiconductor region 52 in this manner enables the electric field applied to the gate insulating film 6 at the bottom 5a of the gate trench 5 to be mitigated. As a result, the electric field applied to the gate insulating film 6 may be mitigated without setting the distance (reference numeral d3 in FIG. 1) from the bottom 5a of the gate trench 5 to the bottom surface of the p-type semiconductor region 13 to be in a predetermined range or greater. Therefore, the depth d2 of the contact trench 8 may be equal to the depth d1 of the gate trench 5 or less (d2≤d1).

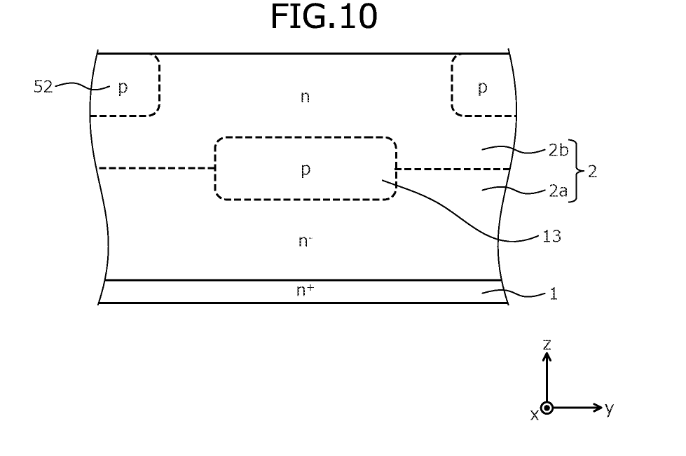

A method of manufacturing the semiconductor device according to the second embodiment will be described taking, as an example, a case where a 3300V trench-type SiC-MOSFET is fabricated. FIGS. 10, 11, and 12 are cross-sectional views of the semiconductor device according to the second embodiment during manufacture. The method of manufacturing the semiconductor device according to the second embodiment, for example, includes in the method of manufacturing the semiconductor device according to the first embodiment, forming the second p-type semiconductor region 52 when the thickness of the second n-type drift region 2b is increased.

In particular, first, on a front surface of a silicon carbide semiconductor substrate (semiconductor wafer) constituting the n⁺-type drain layer 1, the first n⁻-type drift region 2a is formed by epitaxial growth. Next, by photolithography and ion implantation, the p-type semiconductor region 13 is selectively formed in the surface layer of the first n⁻-type drift region 2a and the second n-type drift region 2b is formed in the surface layer of the first n⁻-type drift region 2a. Next, an n⁻-type epitaxial layer having an impurity concentration in a range of, for example, about 1×10¹⁶/cm³ to 1×10¹⁸1 cm³ and a thickness in a range of, for example, about 0.5 μm to 3.0 μm is formed by epitaxial growth so as to cover the p-type semiconductor region 13. Next, at a position along the x direction excluding a position depicted in the cross-sectional views, by photolithography and ion implantation of a p-type impurity such as aluminum (Al), a p-type semiconductor region is provided in the surface layer of the type epitaxial layer, at a depth in a range of about 0.3 μm to 1.5 μm, so as to be in contact with the p-type semiconductor region 13. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b.

Next, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed by epitaxial growth. Next, by photolithography and ion implantation of a p-type impurity such as aluminum (Al), the second p-type semiconductor region 52 is formed in the surface layer of the n⁻-type epitaxial layer, at a depth in a range of about 0.3 μm to 1.5 μm. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b. The width w3 of the p-type semiconductor region 13 may be similar to that in the first embodiment. The width w4 of the second p-type semiconductor region 52 may be in a range of, for example, about 0.3 μm to 2.0 μm. The state up to here is depicted in FIG. 10.

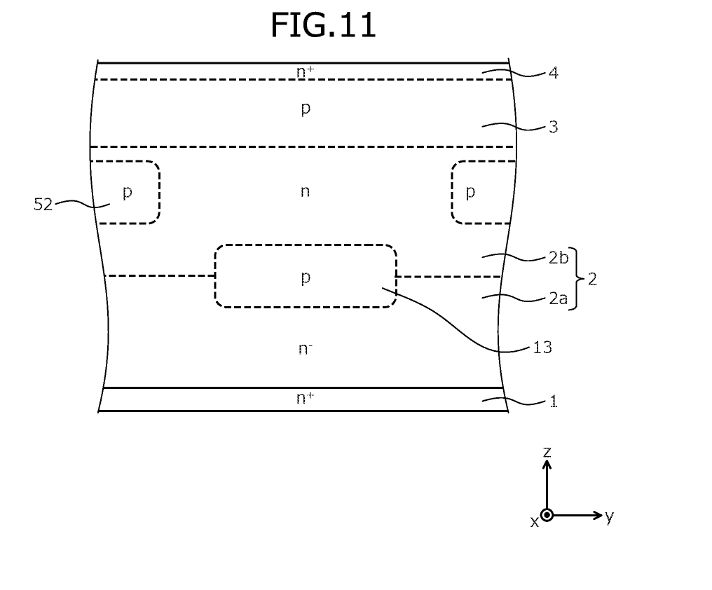

Next, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed on the surface of the second n-type drift region 2b by epitaxial growth, so as to cover the second p-type semiconductor region 52. Next, by photolithography and ion implantation of an n-type impurity such as phosphorus (P) or nitrogen (N), the second n-type drift region 2b is formed from the n⁻-type epitaxial layer increasing the thickness of the second n-type drift region 2b. Next, a p-type epitaxial layer constituting the p-type base region 3 and having a thickness in a range of, for example, about 0.3 μm to 2.0 μm is formed on the surface of the second n-type drift region 2b by epitaxial growth. By the processes up to here, the semiconductor base (silicon carbide epitaxial wafer) 10 is fabricated. Next, by photolithography and ion implantation of an n-type impurity such as phosphorus or nitrogen, the n⁺-type source region 4 is selectively formed in the surface layer of the p-type base region 3. Next, on the base front surface (surface on the n⁺-type source region 4 side), a carbon cap is deposited (formed), activation annealing is performed, and the carbon cap is removed. The state up to here is depicted in FIG. 11.

Next, similarly to the first embodiment, etching is performed using, as a mask, an oxide film that remains, and the contact trench 8 is formed at the depth d2 at which the bottom 8a and the corners 8b reach the p-type semiconductor region 13. Next, the oxide film that remains, for example, is removed by hydrofluoric acid (HF) and thereafter, etching is performed using, as a mask, a remaining part of an oxide film and the gate trench 5 is formed. At this time, the gate trench 5 is formed at the depth d1 at which the bottom 5a and the corners 5b reach the second p-type semiconductor region 52. Here, a case is depicted in which the depth d1 of the gate trench 5 is substantially equal to the depth d2 of the contact trench 8.

The depth d2 of the contact trench 8 may be equal to or less than the depth d1 of the gate trench 5, and may be set to be in the range described in the first embodiment. The width w2 of the contact trench 8, for example, may be the same as that in the first embodiment. The depth d1 of the gate trench 5 may be set to be in the range described in the first embodiment. The width w1 of the gate trench 5 may be equal to that in the first embodiment. The sequence in which the gate trench 5 and the contact trench 8 are formed may be interchanged. Further, when the depth d1 of the gate trench 5 is equal to the depth d2 of the contact trench 8, the gate trench 5 and the contact trench 8 may be formed using a single etching mask.

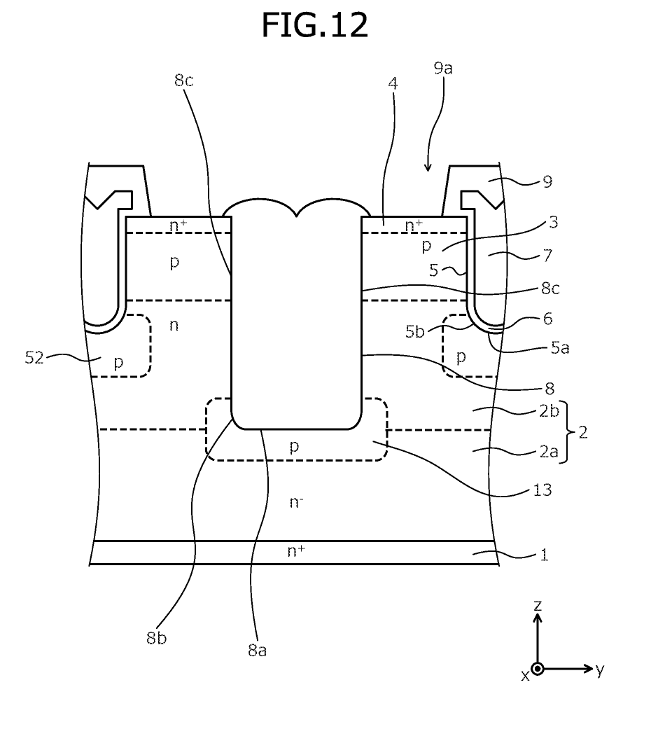

Next, similarly the first embodiment, an oxide film constituting the gate insulating film 6 is formed and thereafter, deposition and patterning of a gate poly-silicon layer constituting the gate electrode 7 are performed. The state up to here is depicted in FIG. 12. Subsequently, similarly to the first embodiment, the process of forming the interlayer insulating film 9 and subsequent processes are sequentially performed, whereby the trench-type SiC-MOSFET depicted in FIG. 9 is completed.

As described, according to the second embodiment, effects similar to those of the first embodiment may be obtained. Further, according to the second embodiment, the second p-type semiconductor region is provided spanning the entire surface of the corners and the bottom of the gate trench, so as to cover the gate electrode, via the gate insulating film, thereby enabling the electric field applied to the gate insulating film at the bottom of the gate trench to be mitigated.

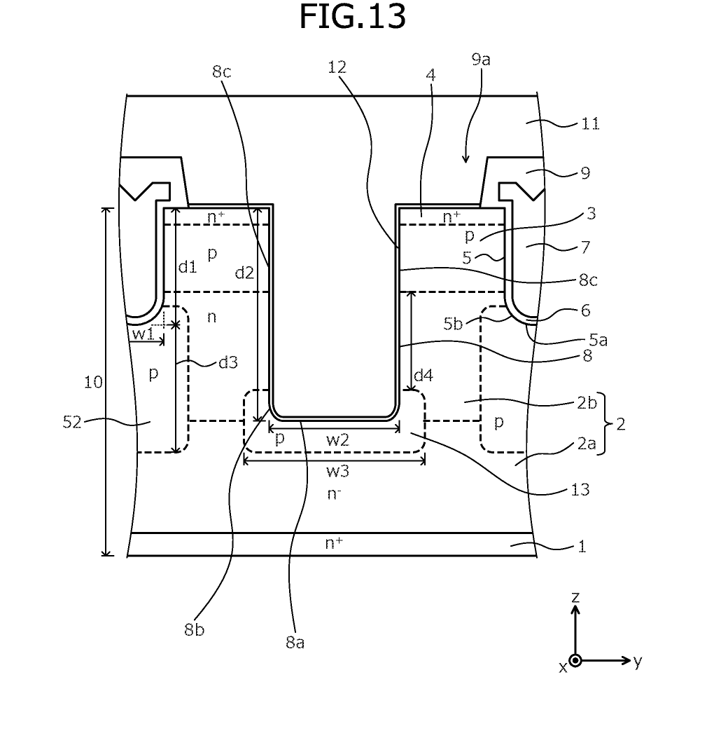

A structure of the semiconductor device according to the third embodiment will be described. FIG. 13 is a cross-sectional view of the structure of the active region of the semiconductor device according to the third embodiment. The semiconductor device according to the third embodiment differs from the semiconductor device according to the first embodiment in that the second p-type semiconductor region 52 is provided. The semiconductor device according to the third embodiment differs from the semiconductor device according to the second embodiment in a shape of the second p-type semiconductor region 52. In the third embodiment, the second p-type semiconductor region 52 reaches the first n⁻-type drift region 2a. In this manner, in the third embodiment, a size of the second p-type semiconductor region 52 is larger than a size thereof in the second embodiment.

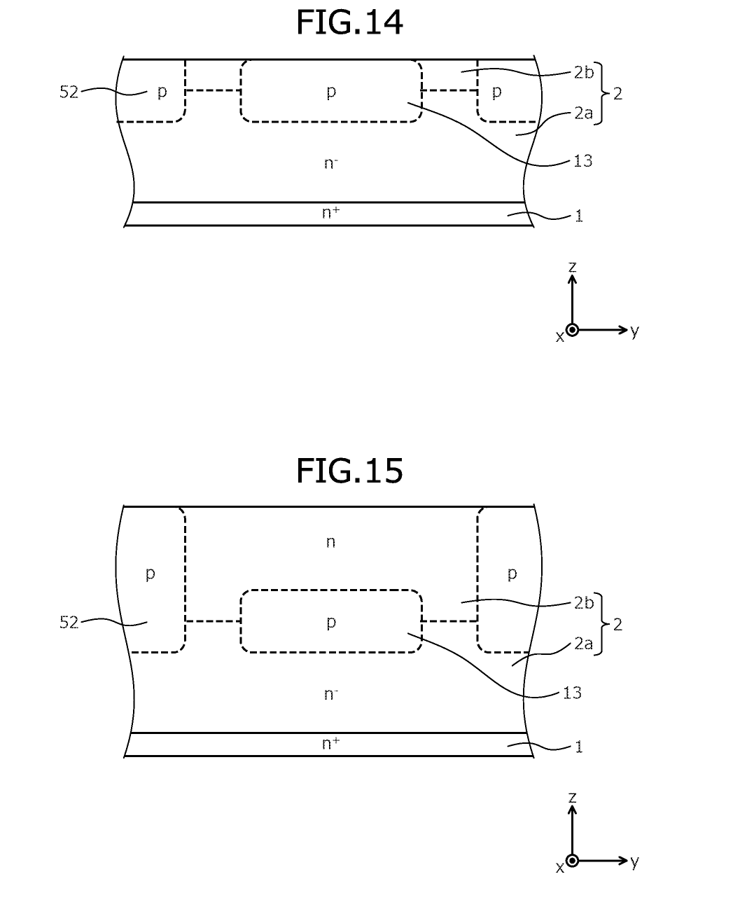

A method of manufacturing the semiconductor device according to the third embodiment will be described taking, as an example, a case in which a 3300V trench-type SiC-MOSFET is fabricated. FIGS. 14 and 15 are cross-sectional views of the semiconductor device according to the third embodiment during manufacture. The method of manufacturing the semiconductor device according to the third embodiment, for example, includes in the method of manufacturing the semiconductor device according to the second embodiment, forming the second p-type semiconductor region 52 when the first n⁻-type drift region 2a is formed, and increasing a thickness of the second p-type semiconductor region 52 when the thickness of the second n-type drift region 2b is increased.

In particular, first, on a front surface of a silicon carbide semiconductor substrate (semiconductor wafer) constituting the n⁺-type drain layer 1, the first n⁻-type drift region 2a is formed by epitaxial growth. Next, by photolithography and ion implantation, the p-type semiconductor region 13 is selectively formed in the surface layer of the first n⁻-type drift region 2a, and the second p-type semiconductor region 52 is selectively formed in the surface layer of the first n⁻-type drift region 2a, at a depth in a range of about 0.3 μm to 1.5 μm. Next, the second n-type drift region 2b is formed in the surface layer of the first n⁻-type drift region 2a by photolithography and ion implantation. The state up to here is depicted in FIG. 14.

Next, by epitaxial growth, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed so as to cover the p-type semiconductor region 13 and the second p-type semiconductor region 52. Next, at a position along the x direction excluding a position depicted in the cross-sectional views, by photolithography and ion implantation of a p-type impurity such as aluminum (Al), a p-type semiconductor region is provided in the surface layer of the n⁻-type epitaxial layer, at a depth in a range of about 0.3 μm to 1.5 μm, so as to be in contact with the p-type semiconductor region 13. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b. Next, by photolithography and ion implantation of a p-type impurity such as aluminum (Al), the second p-type semiconductor region 52 is selectively formed from the n⁻-type epitaxial layer, increasing the thickness of the second p-type semiconductor region 52.

Next, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed by epitaxial growth. Next, by photolithography and ion implantation of a p-type impurity such as aluminum (Al), the second p-type semiconductor region 52 is selectively formed from the surface layer of the n⁻-type epitaxial layer, increasing the thickness of the second p-type semiconductor region 52. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b. The width w3 of the p-type semiconductor region 13 may be equal to that in the first embodiment. The width w4 of the second p-type semiconductor region 52 may be in a range of, for example, about 0.3 μm to 2.0 μm. The state up to here is depicted in FIG. 15.

Next, similarly to the second embodiment, an n⁻-type epitaxial layer is formed by epitaxial growth on the surface of the second n-type drift region 2b, so as to cover the second p-type semiconductor region 52. Next, similarly to the second embodiment, by photolithography and ion implantation, the second n-type drift region 2b is formed from the n⁻-type epitaxial layer, thereby increasing the thickness of the second n-type drift region 2b. Next, similarly to the second embodiment, the p-type base region 3 is formed by epitaxial growth on the surface of the second n-type drift region 2b. By the processes up to here, the semiconductor base (silicon carbide epitaxial wafer) 10 is fabricated. Next, by photolithography and ion implantation, the n⁺-type source region 4 is selectively formed in the surface layer of the p-type base region 3. Next, on the base front surface (surface on the n⁺-type source region 4 side), a carbon cap is deposited (formed), activation annealing is performed, and the carbon cap is removed.

Next, similarly to the second embodiment, etching is performed using, as a mask, an oxide film that remains, the contact trench 8 is formed at the depth d2 at which the bottom 8a and the corners 8b reach the p-type semiconductor region 13. Next, the oxide film that remains, for example, is removed by hydrofluoric acid (HF) and thereafter, etching is performed using, as a mask, a remaining part of an oxide film, and the gate trench 5 is formed. At this time, the gate trench 5 is formed at the depth d1 at which the bottom 5a and the corners 5b reach the second p-type semiconductor region 52. Here, a case is depicted in which the depth d1 of the gate trench 5 is substantially equal to the depth d2 of the contact trench 8.

The depth d2 of the contact trench 8 may be equal to or less than the depth d1 of the gate trench 5, and may be set to be in a predetermined range equal to that in the second embodiment. The width w2 of the contact trench 8 may be, for example, equal to that in the second embodiment. The depth d1 of the gate trench 5 may be set to be in a range equal to the range in the second embodiment. The width w1 of the gate trench 5 may be equal to that in the second embodiment. The sequence in which the gate trench 5 and the contact trench 8 are formed may be interchanged. Further, when the depth d1 of the gate trench 5 is equal to the depth d2 of the contact trench 8, the gate trench 5 and the contact trench 8 may be etched using a single mask.

Next, similarly to the second embodiment, an oxide film constituting the gate insulating film 6 is formed and thereafter, deposition and patterning of a gate poly-silicon layer constituting the gate electrode 7 are performed. Thereafter, similarly to the second embodiment, the process of forming the interlayer insulating film 9 and subsequent processes are sequentially performed, whereby the trench-type SiC-MOSFET depicted in FIG. 13 is completed.

As described, according to the third embodiment, effects similar to those of the first embodiment may be obtained. Further, according to the third embodiment, the second p-type semiconductor region is provided, enabling effects similar to those of the second embodiment to be obtained.

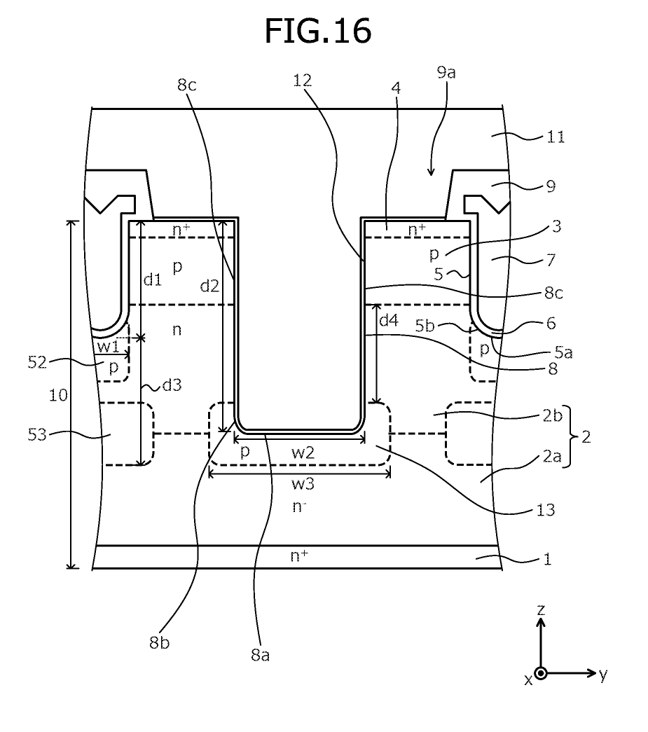

A structure of the semiconductor device according to a fourth embodiment will be described. FIG. 16 is a cross-sectional view of the structure of the active region of the semiconductor device according to the fourth embodiment. The semiconductor device according to the fourth embodiment differs from the semiconductor device according to the first embodiment in that the second p-type semiconductor region 52 is provided and a p-type semiconductor region (hereinafter, third p-type semiconductor region (fourth semiconductor region) 53 is provided at an interface of the first n⁻-type drift region 2a and the second n-type drift region 2b. The third p-type semiconductor region 53 is in contact with the first n⁻-type drift region 2a and the second n-type drift region 2b.

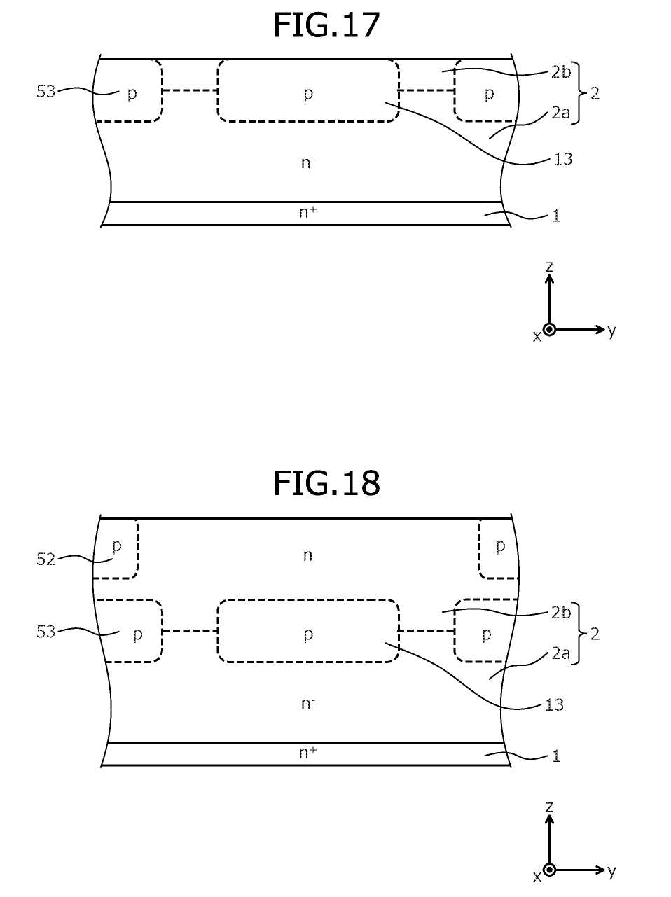

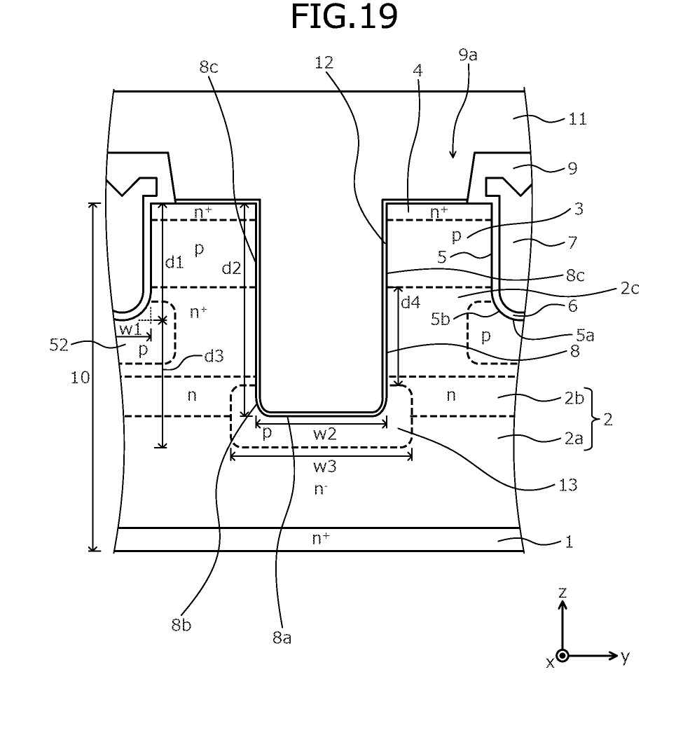

A method of manufacturing the semiconductor device according to the fourth embodiment will be described taking, as an example, a case where a 1200V trench-type SiC-MOSFET is fabricated. FIGS. 17 and 18 are cross-sectional views of the semiconductor device according to the fourth embodiment during manufacture. The method of manufacturing the semiconductor device according to the fourth embodiment, for example, includes in the method of manufacturing the semiconductor device according to the second embodiment, forming the third p-type semiconductor region 53 when the first n⁻-type drift region 2a is formed.

In particular, first, on a front surface of a silicon carbide semiconductor substrate (semiconductor wafer) constituting the n⁺-type drain layer 1, the first n⁻-type drift region 2a having a thickness of about 10 μm is formed by epitaxial growth. Next, by photolithography and ion implantation, the p-type semiconductor region 13 is selectively formed in the surface layer of the first n⁻-type drift region 2a, and the third p-type semiconductor region 53 is selectively formed in the surface layer of the first n⁻-type drift region 2a, at a depth in a range of about, 0.3 μm to 1.5 μm. Next, by photolithography and ion implantation, the second n-type drift region 2b is formed in the surface layer of the first n⁻-type drift region 2a. The state up to here is depicted in FIG. 17.

Next, an n⁻-type epitaxial layer having an impurity concentration of, for example, about 1×10¹⁶/cm³ to 1×10¹⁸/cm³ and a thickness in a range of, for example, about 0.5 μm to 3.0 μm is formed by epitaxial growth, so as to cover the p-type semiconductor region 13 and the third p-type semiconductor region 53. Next, at a position along the x direction excluding a position depicted in the cross-sectional views, by photolithography and ion implantation of a p-type impurity such as aluminum (Al), a p-type semiconductor region is provided in the surface layer of the n⁻-type epitaxial layer, at a depth in a range of about 0.3 μm to 1.5 μm, so as to be in contact with the p-type semiconductor region 13. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b.

Next, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed by epitaxial growth. Next, by photolithography and ion implantation of a p-type impurity such as aluminum (Al), the second p-type semiconductor region 52 is selectively formed from the surface layer of the n⁻-type epitaxial layer. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b. The width w3 of the p-type semiconductor region 13 may be equal to that in the first embodiment. The width w4 of the second p-type semiconductor region 52 may be in a range of, for example, about 0.3 μm to 2.0 μm. The state up to here is depicted in FIG. 18.

Next, similarly to the second embodiment, an n⁻-type epitaxial layer is formed by epitaxial growth on the surface of the second n-type drift region 2b, so as to cover the second p-type semiconductor region 52. Next, similarly the second embodiment, by photolithography and ion implantation, the second n-type drift region 2b is formed from the n⁻-type epitaxial layer, thereby increasing the thickness of the second n-type drift region 2b. Next, similarly to the second embodiment, the p-type base region 3 is formed by epitaxial growth on the surface of the second n-type drift region 2b. By the processes up to here, the semiconductor base (silicon carbide epitaxial wafer) 10 is fabricated. Next, by photolithography and ion implantation, the n⁺-type source region 4 is selectively formed in the surface layer of the p-type base region 3. Next, on the base front surface (surface on the n⁺-type source region 4 side), a carbon cap is deposited (formed), activation annealing is performed, and the carbon cap is removed.

Next, similarly to the second embodiment, etching is performed using, as a mask, the oxide film that remains, and the contact trench 8 is formed at the depth d2 at which the bottom 8a and the corners 8b reach the p-type semiconductor region 13. Next, the oxide film that remains, for example, is removed by hydrofluoric acid (HF) and thereafter, etching is performed using, as a mask, a remaining part of an oxide film, and the gate trench 5 is formed. At this time, the gate trench 5 is formed at the depth d1 at which the bottom 5a and the corners 5b reach the second p-type semiconductor region 52. Here, a case is depicted in which the depth d1 of the gate trench 5 is equal to the depth d2 of the contact trench 8.

The depth d2 of the contact trench 8 may be equal to or less than the depth d1 of the gate trench 5, and may be in a range equal to that in the second embodiment. The width w2 of the contact trench 8 may be, for example, equal to that in the second embodiment. The depth d1 of the gate trench 5 may be set to in a range equal to that in the second embodiment. The width w1 of the gate trench 5 may be equal to that in the second embodiment. The sequence in which the gate trench 5 and the contact trench 8 are formed may be interchanged. Further, when the depth d1 of the gate trench 5 is equal to the depth d2 of the contact trench 8, the gate trench 5 and the contact trench 8 may be formed using a single mask.

Next, similarly to the second embodiment, an oxide film constituting the gate insulating film 6 is formed and thereafter, deposition and patterning of a gate poly-silicon layer constituting the gate electrode 7 are performed. Thereafter, similarly to the second embodiment, the process of forming the interlayer insulating film 9 and subsequent processes sequentially are performed, whereby the trench-type SiC-MOSFET depicted in FIG. 16 is completed.

As described, according to the fourth embodiment, effects similar to those of the first embodiment may be obtained. Further, according to the fourth embodiment, the second p-type semiconductor region is provided spanning the entire surface of the corners and the bottom of the gate trench, so as to cover the gate electrode, via the gate insulating film, thereby enabling effects similar to those of the second embodiment to be obtained.

A structure of the semiconductor device according to a fifth embodiment will be described. FIG. 19 is a cross-sectional view of the structure of the active region of the semiconductor device according to the fifth embodiment. The semiconductor device according to the fifth embodiment differs from the semiconductor device according to the second embodiment in that an n⁺-type region (first silicon carbide semiconductor region of a first conductivity type) (hereinafter, third n⁺-type drift region) 2c is provided at the surface of the second n-type drift region 2b. The third n⁺-type drift region 2c is selectively provided at the surface of the second n-type drift region 2b and is in contact with the side walls 8c of the contact trench 8.

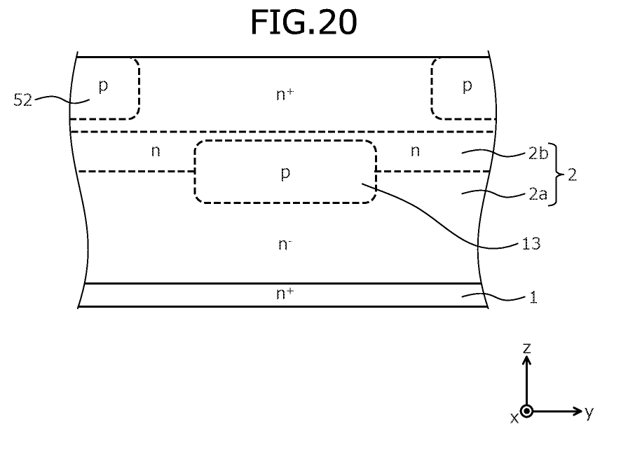

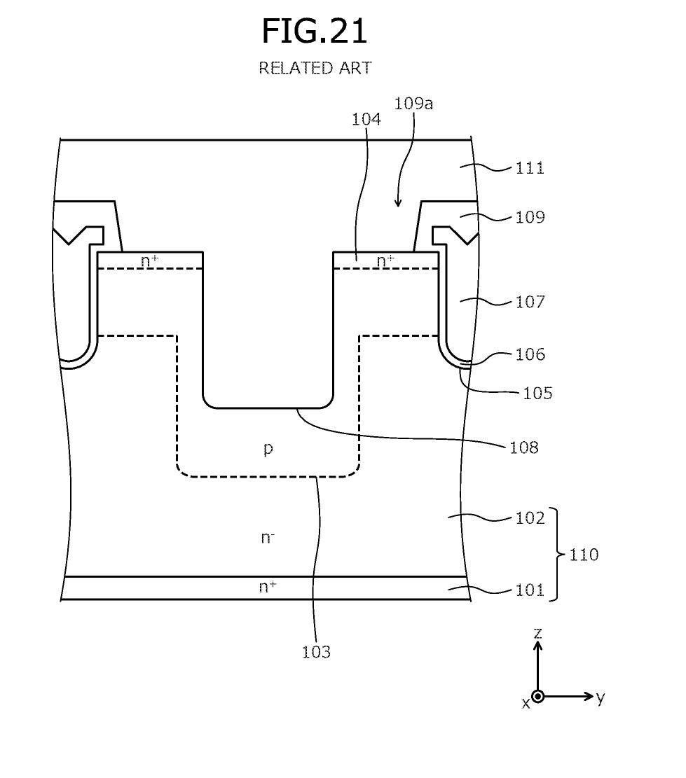

A method of manufacturing the semiconductor device according to the fifth embodiment will be described taking, as an example, a case in which a 1200V trench-type SiC-MOSFET is fabricated. FIG. 20 is a cross-sectional view of the semiconductor device according to the fifth embodiment during manufacture. The method of manufacturing the semiconductor device according to the fifth embodiment, for example, includes in the method of manufacturing the semiconductor device according to the second embodiment, selectively forming the third n⁺-type drift region 2c at the surface of the second n-type drift region 2b.

In particular, first, on a front surface of a silicon carbide semiconductor substrate (semiconductor wafer) constituting the n⁺-type drain layer 1, the first n⁻-type drift region 2a having a thickness of about 10 μm is formed by epitaxial growth. Next, by photolithography and ion implantation, the p-type semiconductor region 13 is selectively formed in the surface layer of the first n⁻-type drift region 2a, and the second n-type drift region 2b is formed in the surface layer of the first n⁻-type drift region 2a.

Next, by epitaxial growth, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed so as to cover the p-type semiconductor region 13. Next, at a position along the x direction excluding a position depicted in the cross-sectional views, by photolithography and ion implantation of a p-type impurity such as aluminum (Al), a p-type semiconductor region is provided in the surface layer of the n⁻-type epitaxial layer, at a depth in a range of about 0.3 μm to 1.5 μm, so as to be in contact with the p-type semiconductor region 13. Next, by photolithography and ion implantation of an n-type impurity such as phosphorus (P) or nitrogen (N), the second n-type drift region 2b is formed from the n⁻-type epitaxial layer, thereby increasing the thickness of the second n-type drift region 2b.

Next, an n⁻-type epitaxial layer having an impurity concentration in a range of, for example, about 1×10¹⁶/cm³ to 1×10¹⁸/cm³ and a thickness in a range of, for example, about 0.5 μm to 3.0 μm is formed by epitaxial growth. Next, by photolithography and ion implantation of an n-type impurity such as phosphorus (P) or nitrogen (N), the third n⁺-type drift region 2c is formed from the n⁻-type epitaxial layer. Next, by photolithography and ion implantation of a p-type impurity such as aluminum (Al), the second p-type semiconductor region 52 is selectively formed in the surface layer of the third n⁺-type drift region 2c, at a depth in a range of about 0.3 μm to 1.5 μm. The width w3 of the p-type semiconductor region 13 may be equal to that in the first embodiment. The width w4 of the second p-type semiconductor region 52 may in a range of, for example, about 0.3 μm to 2.0 μm. The state up to here is depicted in FIG. 20.

Next, similarly to the second embodiment, an n⁻-type epitaxial layer is formed by epitaxial growth on the surface of the second n-type drift region 2b, so as to cover the second p-type semiconductor region 52. Next, similarly to the second embodiment, by photolithography and ion implantation, the second n-type drift region 2b is formed from the n⁻-type epitaxial layer, thereby increasing the thickness of the second n-type drift region 2b. Next, similarly to the second embodiment, the p-type base region 3 is formed by epitaxial growth on the surface of the second n-type drift region 2b. By the processes up to here, the semiconductor base (silicon carbide epitaxial wafer) 10 is fabricated. Next, by photolithography and ion implantation, the n⁺-type source region 4 is selectively formed in the surface layer of the p-type base region 3. Next, on the base front surface (surface on the n⁺-type source region 4 side), a carbon cap is deposited (formed), activation annealing is performed, and the carbon cap is removed.

Next, similarly to the second embodiment, etching is performed using, as a mask, an oxide film that remains, and the contact trench 8 is formed at the depth d2 at which the bottom 8a and the corners 8b reach the p-type semiconductor region 13. Next, the oxide film that remains, for example, is removed by hydrofluoric acid (HF) and thereafter, etching is performed using, as a mask, a remaining part of an oxide film, and the gate trench 5 is formed. At this time, the gate trench 5 is formed at the depth d1 at which the bottom 5a and the corners 5b reach the second p-type semiconductor region 52. Here, a case is depicted in which the depth d1 of the gate trench 5 is equal to the depth d2 of the contact trench 8.

The depth d2 of the contact trench 8 may be equal to or less than the depth d1 of the gate trench 5, and may be set to be in a range equal to that in the second embodiment. The width w2 of the contact trench 8, for example, may be equal to that in the second embodiment. The depth d1 of the gate trench 5 may be set to be in a range equal to that in the second embodiment. The width w1 of the gate trench 5 may be equal to that in the second embodiment. The sequence in which the gate trench 5 and the contact trench 8 are formed may be interchanged. Further, when the depth d1 of the gate trench 5 is equal to the depth d2 of the contact trench 8, the gate trench 5 and the contact trench 8 may be formed using a single mask.

Next, similarly to the second embodiment, an oxide film constituting the gate insulating film 6 is formed and thereafter, disposition and patterning of a gate poly-silicon layer constituting the gate electrode 7 are performed. Thereafter, similarly to the second embodiment, the process of forming the interlayer insulating film 9 and subsequent processes are sequentially performed, whereby the trench-type SiC-MOSFET depicted in FIG. 19 is completed.

As described, according to the fifth embodiment, effects similar to those of the first embodiment may be obtained. Further, according to the fifth embodiment, the third n⁺-type drift region is not in contact with the gate trench, enabling effects similar to the second embodiment to be obtained. According to the fifth embodiment, the third n⁺-type drift region having an impurity concentration that is higher than that of the second n-type drift region is provided between the second n-type drift region and the p-type base region. Here, at the n-type drift region between the p-type regions (the p-type semiconductor region and the p-type base region), parasitic resistance tends to occur and resistance of the n-type drift region increases due to this parasitic resistance. By increasing the impurity concentration of the third n⁺-type drift region between the p-type regions, the resistance of the n-type drift region may be reduced. As a result, when the parasitic Schottky diode is ON, hole current decreases, enabling the parasitic pn diode to be prevented from turning ON.

The contact trench is not limited to a U-shape and may have a V-shape. Further, the interface of the second n-type drift region 2b and the p-type base region 3 may be shallower toward the contact trench and the mathematical area of the Schottky junction may be increased. In this case, the second n-type drift region 2b and the n⁺-type source region are structured so as to not contact each other.

In the embodiments of the present invention, various modifications within a range not deviating from the spirit of the invention are possible. For example, dimensions, impurity concentrations, etc. of regions may be variously changed according to required formation conditions of the regions. Further, in the embodiments while the first conductivity type is assumed to be an n-type and a second conductivity type is assumed to be a p-type, the present invention is similarly implemented when the first conductivity type is a p-type and the second conductivity type is an n-type.

According to the embodiments of the present invention, the mathematical area of the part of the side walls of contact trench (second trench) forming the Schottky junction is a predetermined mathematical area or greater. As a result, the current that flows through the parasitic pn diode relative to the current that flows through the parasitic Schottky diode may be set to 1.0 or less; the current that flows through the parasitic pn diode at the time of flyback may be reduced; and the occurrence of defects in the parasitic pn diode may be reduced. Therefore, the occurrence of defects in the parasitic pn diode is suppressed, enabling forward loss to be reduced.

The semiconductor device and the method of manufacturing a semiconductor device according to the embodiments of the present invention achieve an effect in that bipolar operation of the parasitic pn diode is suppressed and forward loss is reduced.

As described, the semiconductor device and the method of manufacturing a semiconductor device according to the embodiments of the present invention are useful for semiconductor devices used in power converting equipment such as converters and inverters, and are particularly suitable for silicon carbide semiconductor devices having a trench gate structure.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a first silicon carbide semiconductor layer of a first conductivity type;
a second silicon carbide semiconductor layer of the first conductivity type provided on a surface of the first silicon carbide semiconductor layer and having an impurity concentration that is lower than that of the first silicon carbide semiconductor layer;
a first semiconductor region of a second conductivity type selectively provided in the second silicon carbide semiconductor layer, at a position deeper than that of a surface of the second silicon carbide semiconductor layer;
a third silicon carbide semiconductor layer of the second conductivity type provided on the surface of the second silicon carbide semiconductor layer;
a second semiconductor region of the first conductivity type selectively provided in the third silicon carbide semiconductor layer;
a first trench that penetrates the second semiconductor region and the third silicon carbide semiconductor layer, and reaches the second silicon carbide semiconductor layer;
a second trench provided separated from the first trench, the second trench penetrating the second semiconductor region and the third silicon carbide semiconductor layer, and reaching the first semiconductor region, through the second silicon carbide semiconductor layer;
a gate insulating film provided in the first trench;
a gate electrode provided in the first trench on the gate insulating film; and
a metal electrode in contact with the second semiconductor region and the third silicon carbide semiconductor layer, the metal electrode being embedded in the second trench so as to be in contact with the first semiconductor region at a bottom and corners of the second trench, the metal electrode forming a Schottky junction with the second silicon carbide semiconductor layer at a side wall of the second trench,
wherein the second trench has a depth that is a depth by which a mathematical area of the metal electrode forming the Schottky junction is at least a predetermined mathematical area.

2. The semiconductor device according to claim 1 and further comprising a third semiconductor region of the second conductivity type selectively provided in the second silicon carbide semiconductor layer, the third semiconductor region opposing the gate electrode at the bottom and the corners of the first trench, across the gate insulating film.

3. The semiconductor device according to claim 2, wherein the third semiconductor region and the second silicon carbide semiconductor layer nearest the first silicon carbide semiconductor layer have an interface having a depth,
wherein the first semiconductor region and the second silicon carbide semiconductor layer nearest the first silicon carbide semiconductor layer have an interface having a depth, and
wherein depth of the interface of the third semiconductor region and the second silicon carbide semiconductor layer nearest the first silicon carbide semiconductor layer and the depth of the interface of the first semiconductor region and the second silicon carbide semiconductor layer nearest the first silicon carbide semiconductor layer are equal.

4. The semiconductor device according to claim 2 and further comprising a fourth semiconductor region of the second conductivity type provided in the second silicon carbide semiconductor layer, at a position deeper than that of the third semiconductor region,
wherein the fourth semiconductor region and the second silicon carbide semiconductor layer nearest the first silicon carbide semiconductor layer have an interface having a depth, and the first semiconductor region and the second silicon carbide semiconductor layer nearest the first silicon carbide semiconductor layer have an interface having a depth, and
wherein the depth of the interface of the fourth semiconductor region and the second silicon carbide semiconductor layer nearest the first silicon carbide semiconductor layer and the depth of the first semiconductor region and the second silicon carbide semiconductor layer nearest the first silicon carbide semiconductor layer are equal.

5. The semiconductor device according to claim 2, further comprising a first silicon carbide semiconductor region of the second conductivity type provided on the surface of the second silicon carbide semiconductor layer and having an impurity concentration that is being higher than that of the second silicon carbide semiconductor layer,
wherein the third silicon carbide semiconductor layer is provided on a first side of the first silicon carbide semiconductor region opposite a second side of the first silicon carbide semiconductor region, the second side facing the second silicon carbide semiconductor layer,
wherein the first semiconductor region is provided in the second silicon carbide semiconductor layer, closer to the first silicon carbide semiconductor layer than is an interface of the second silicon carbide semiconductor layer and the first silicon carbide semiconductor region, and
the third semiconductor region is provided in the first silicon carbide semiconductor region.

6. The semiconductor device according to claim 1, wherein the first semiconductor region has a width that is wider than that of second trench.

7. The semiconductor device according to claim 1, wherein the second trench has a depth that is at least equal to that of the first trench.

8. The semiconductor device according to claim 1, wherein the second trench has a depth ranging from 1.8 μm to 3.0 μm.
